(19) United States
(12) Patent Application Publication
(10) Pub. No.: US 2017/0035172 A1
(43) Pub. Date: Feb. 9, 2017

(54) MAGNETIC MOUNT FOR ELECTRONIC DEVICES

(71) Applicant: SPIGEN KOREA CO., LTD., Seoul (KR)

(72) Inventor: Dae-Young KIM, Seoul (KR)

(21) Appl. No.: 15/231,483

(22) Filed: Aug. 8, 2016

Related U.S. Application Data
(60) Provisional application No. 62/202,058, filed on Aug. 6, 2015.

(51) Int. Cl. A45C 13/10; F16M 13/00; F16B 1/00; H04B 1/3888; B60R 11/02; A45C 11/00; A45C 13/00; A45F 5/00; H05K 5/02; F16B 47/00

(52) U.S. Cl. CPC A45C 13/1069; H05K 5/0204; F16M 13/00; F16B 1/00; F16B 47/003; B60R 11/02; A45C 11/00; A45C 13/002; A45F 5/00; H04B 1/3888; F16B 2001/0035; B60R 2011/0008

(57) ABSTRACT

A magnetic mount includes a case and a support. The case includes a soft protective cover, a hard protective frame configured to removably mount over the soft protective cover, and a first member placed between the soft protective cover and the hard protective frame. The soft protective cover includes a back panel to cover a back portion of the electronic device, and a side wall extending from a top surface of the back panel along edges of the back panel The support has a second member and the first and second members are magnetically attractable to each other for magnetically attracting and retaining the case to the support.

### CROSS-REFERENCE TO RELATED APPLICATIONS

This application claims priority to U.S. provisional patent application No. 62/202,058, filed Aug. 6, 2015, which is incorporated herein by reference.

### FIELD OF THE INVENTION

The present invention relates to a magnetic mount for an electronic device and, more particularly, to a mobile phone mount having magnetically attractable members one of which is installed in a case and the other of which is installed in a support. The support supports the case so that the case stands or the support can be mounted on an air vent of a vehicle. In the alternative embodiment, the magnetic mount includes a first member and a support having a second member. The first member is constructed to be attachable to a back of an electronic device or a case and the first and second members are magnetically attractable to each other.

### SUMMARY OF THE INVENTION

The present invention contrives to solve the disadvantages of the prior art. The present invention provides a magnetic mount, having a case and a support, for an electronic device such as a mobile phone or a smart phone, and, more particularly, to a magnetic mount having a case and a support such that the case and the support are magnetically attracted to each other.

The object of the present invention is to provide a magnetic mount having a case and a support. The case includes a soft protective cover, a hard protective frame and a first member placed between the soft protective cover and the hard protective frame. The soft protective cover comprises a back panel to cover a back portion of the electronic device, and a side wall extending from a top surface of the back panel along edges of the back panel. The support has a second member and the first and second members are magnetically attractable to each other for magnetically attracting and retaining the case to the support. In addition, a soft protective cover, a hard protective frame or both has a recess(es) to receive the first member therein.

Another object of the present invention is to provide a magnetic mount having a first member and a support having a second member. The first member is constructed to be attachable to a back of a case or an electronic device by adhesive. The first member is made of ferromagnetic material and the second member is made of a magnet which produces magnetic flux.

The advantages of the present invention are: (1) the case of the present invention is constructed to be magnetically attracted and retained by the support and thus, the connection between the case and the support is convenient; (2) the support of the present invention is constructed to prop or support the case so that the case can stand on a flat surface; (3) the support of the present invention is constructed to be securely retained by an air vent of a vehicle so that the case can be securely mounted on the air vent; and (4) when the case is magnetically retained by the support, the case can stand on a flat surface and the angle between the case and the flat surface can be adjusted by adjusting the location of the support with respect to the case.

Although the present invention is briefly summarized, the fuller understanding of the invention can be obtained by the following drawings, detailed description and appended claims.

### BRIEF DESCRIPTION OF THE DRAWINGS

These and other features, aspects and advantages of the present invention will become better understood with reference to the accompanying drawings, wherein:

FIG. 1 shows a front perspective view of a case according to the present invention;

FIG. 2 shows a rear perspective view of the case according to the present invention;

FIG. 3 shows an exploded view of the case having a soft protective cover, a hard protective frame and a first member according to the present invention;

FIG. 4 shows a rear view of the case according to the present invention;

FIG. 5 shows a cross sectional view of FIG. 4;

FIG. 6 shows a schematic perspective view of a magnetic mount illustrating magnetic attraction between the support and the first member to support or retain an electronic device according to the present invention;

FIG. 7 shows a perspective view of the magnetic mount having the case and the support such that the support magnetically attracts and retains the case so that the case can stand on a flat surface;

FIG. 8 shows a perspective view of the magnetic mount having the case and the support such that the support magnetically attracts and retains the case and the support is inserted and securely retained by an air vent of a vehicle;

FIG. 9 shows another exploded view of the case having the soft protective cover, the hard protective frame and the first member according to the present invention; and

FIG. 10 shows the support, the first member shaped in a circular metal plate, and the first member shaped in a rectangular metal plate.

### DETAILED DESCRIPTION EMBODIMENTS OF THE INVENTION

Reference will now be made in detail to the preferred embodiments of the present invention, examples of which are illustrated in the accompanying drawings, which form a part of this disclosure. It is to be understood that this invention is not limited to the specific devices, methods, conditions or parameters described and/or shown herein, and that the terminology used herein is for the purpose of describing particular embodiments by way of example only and is not intended to be limiting of the claimed invention.

Also, as used in the specification including the appended claims, the singular forms “a”, “an”, and “the” include the plural, and reference to a particular numerical value includes at least that particular value, unless the context clearly dictates otherwise. Ranges may be expressed herein as from “about” or “approximately” one particular value and/or to “about” or “approximately” another particular value. When such a range is expressed, another embodiment includes from the one particular value and/or to the other particular value. Similarly, when values are expressed as approximations, by use of the antecedent “about”, it will be understood that the particular value forms another embodiment.

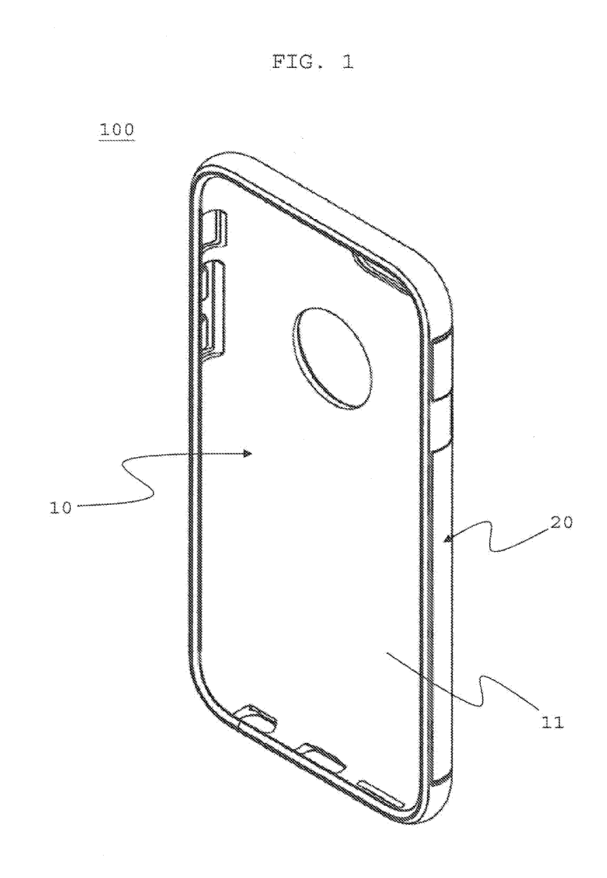

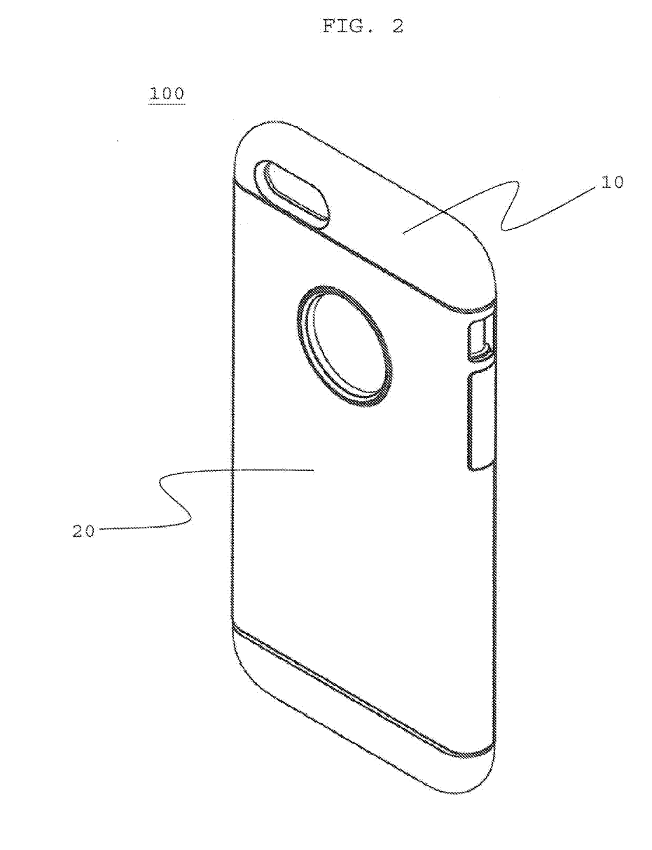

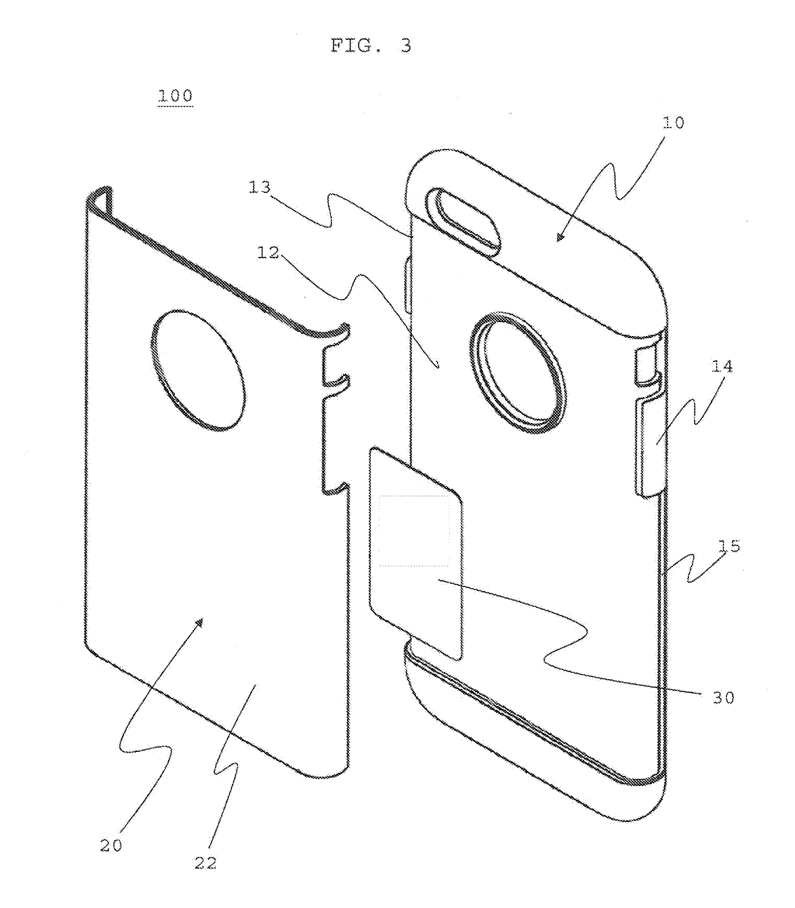

FIGS. 1 and 2 respectively show front and rear perspective views of a case 100 according to the present invention. FIG. 3 shows an exploded view of the case 100 having a soft protective cover 10, a hard protective frame 20 and a first member 30.

A magnetic mount 200 of the present invention for an electronic device 300 comprises: a case 100 and a support 40. The case 100 comprises a soft protective cover 10 which comprises a back panel 12 to cover a back portion of the electronic device 300, and a side wall 14 extending from a top surface 11 of the back panel 12 along edges 13 of the back panel 12; a hard protective frame 20 constructed to removably mount over the soft protective cover 10; and a first member 30 placed between the soft protective cover 10 and the hard protective frame 20. The support has a second member 50. In addition, the first and second members 30, 50 are magnetically attractable to each other for magnetically attracting and retaining the case 100 to the support 40.

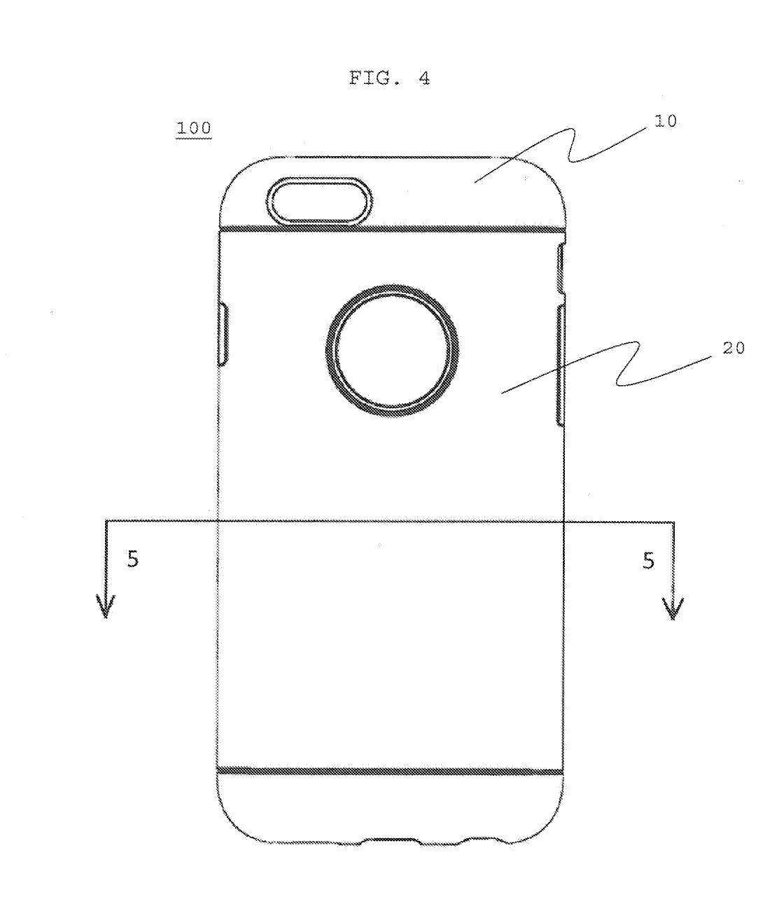

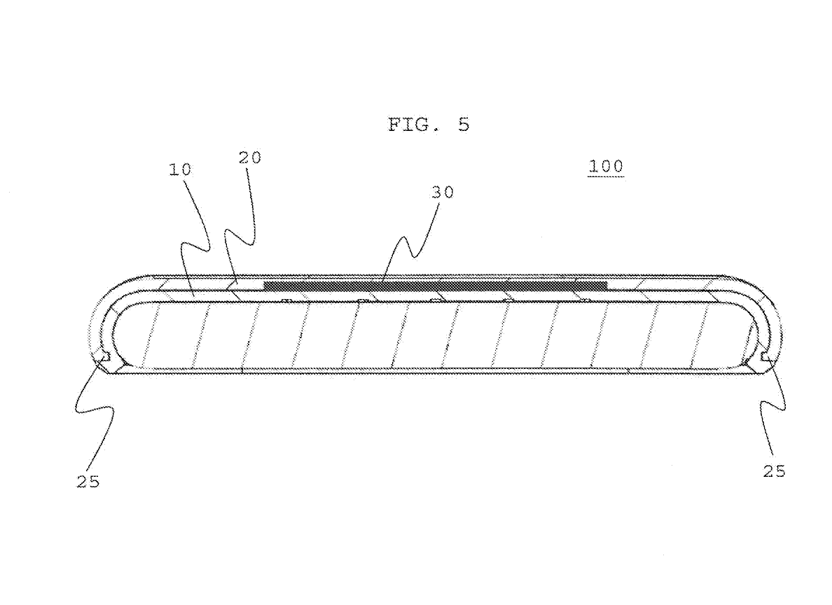

FIG. 4 shows a rear view of the case 100 and FIG. 5 shows a cross sectional view of FIG. 4.

The soft protective cover 10 may have a recess (not shown) formed on the back panel 12 to receive the first member 30. In the alternative as shown in FIG. 5, the hard protective frame 20 may have a recess to receive the first member 30. Or, the soft protective cover 10 may have a first recess formed on the back panel 12 and the hard protective frame 20 may have a second recess such that the first and second recesses form a housing to receive the first member 30 therein.

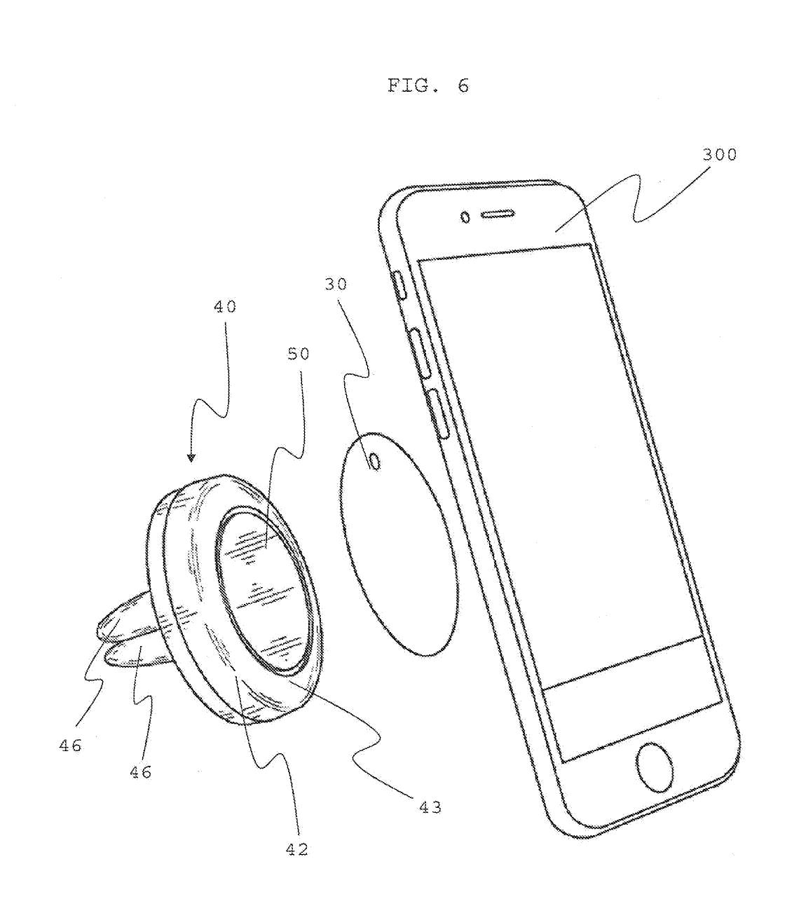

FIG. 6 shows a schematic perspective view of the magnetic mount 200 illustrating magnetic attraction between the support 40 and the first member 30 to support or retain the electronic device 300.

The support 40 comprises a body 42 and a plurality of legs 46, wherein the body 42 is substantially in a form of a geometric prism or cylinder which has two bases 43, 44 facing each other wherein the legs 46 are attached to one 44 of the two bases 43, 44, wherein the second member 50 is placed in the body 42. One base 43 of the support 40 has a flat surface to be magnetically attached to the case (100).

The body 42 is substantially in a shape of a prism, a right prism, a uniform prism, or cylinder. Preferably, the body is substantially cylindrical or substantially in a shape of a right prism having two bases of regular convex and rectangular sides, for example, regular hexagon right prism, regular octagon right prism, or the like.

When the case 100 is magnetically retained by the support 40, the base 43 of the body 42 and an outer surface 22 of the hard protective frame 20 create enough friction to prevent the case 100 from sliding on the base 43. To create such friction, the surface of the base 43 may be rough.

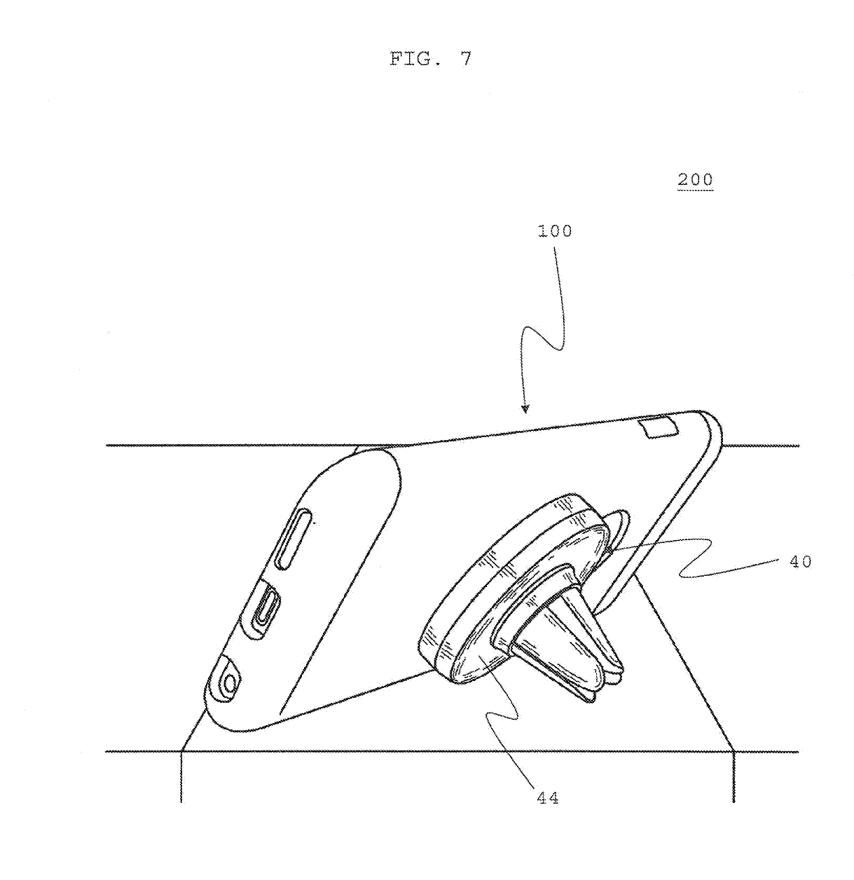

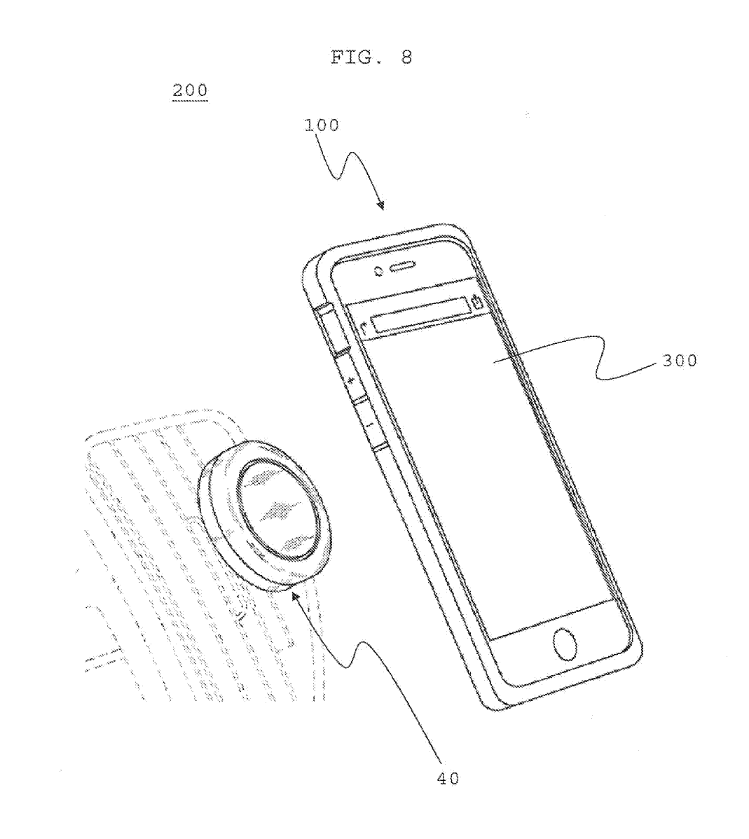

FIG. 7 shows a perspective view of the magnetic mount 200 such that the support 40 magnetically attracts and retains the case 100 so that the case 100 can stand on a flat surface. FIG. 8 shows a perspective view of the magnetic mount 200 such that the support 40 magnetically attracts and retains the case 100 and the support 40 is inserted into and securely retained by an air vent of a vehicle which is comprised of parallel vanes.

The plurality of legs 46 of the support 40 are configured to support the case 100 magnetically retained by the support 40 so that the case 100 stands on a flat surface. When the case 100 is magnetically retained by the support 40, the case 100 can stand on a flat surface and the angle between the case 100 and the flat surface can be adjusted by adjusting the location of the support 40 with respect to the case 100. The adjusted location can be maintained. The friction between the case 100 and the support 40 should be weak enough to allow such location adjustment, but strong enough to prevent slipping of the case 100 away from the support 40.

In addition, the plurality of legs 46 of the support 40 is constructed to be received and retained by an air vent of a vehicle. FIG. 8 shows the support 40 inserted into and retained by the air vent of a vehicle. By the magnetic attraction between the support 40 and the case 100, the case 100 can be mounted onto the air vent of a vehicle. The support 40 is detachably fixed to the air vent and the case 100 can rotate or slide a little with respect to the support 40. Because of friction between the support 40 and the case 100, adjusted rotation or sliding of the case 100 can be maintained so that a user can adjust the angle of the case 100 suitable and convenient for him.

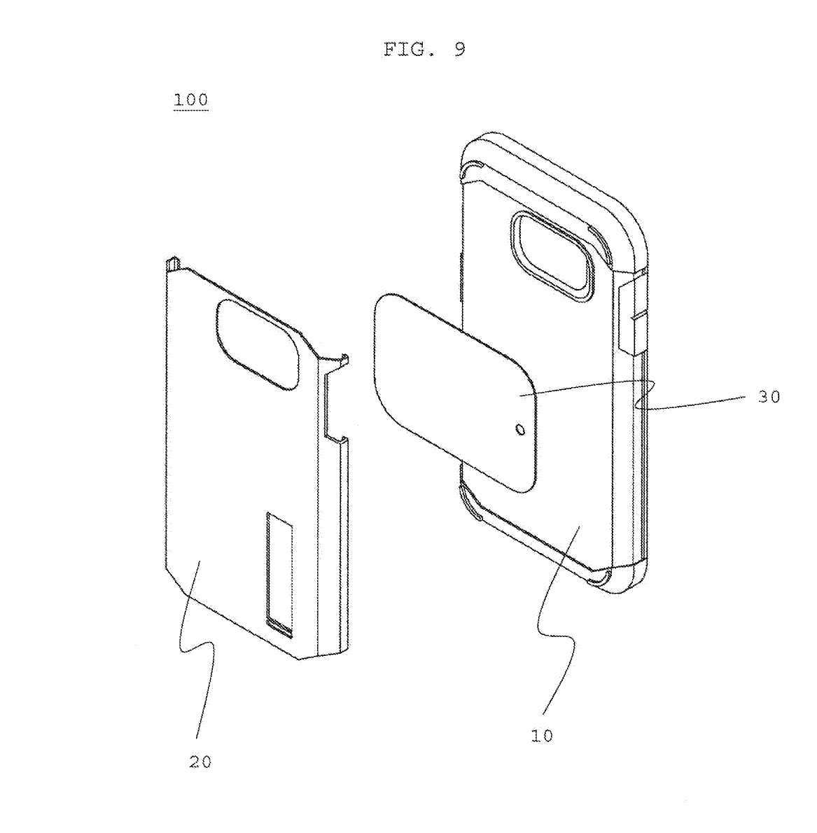

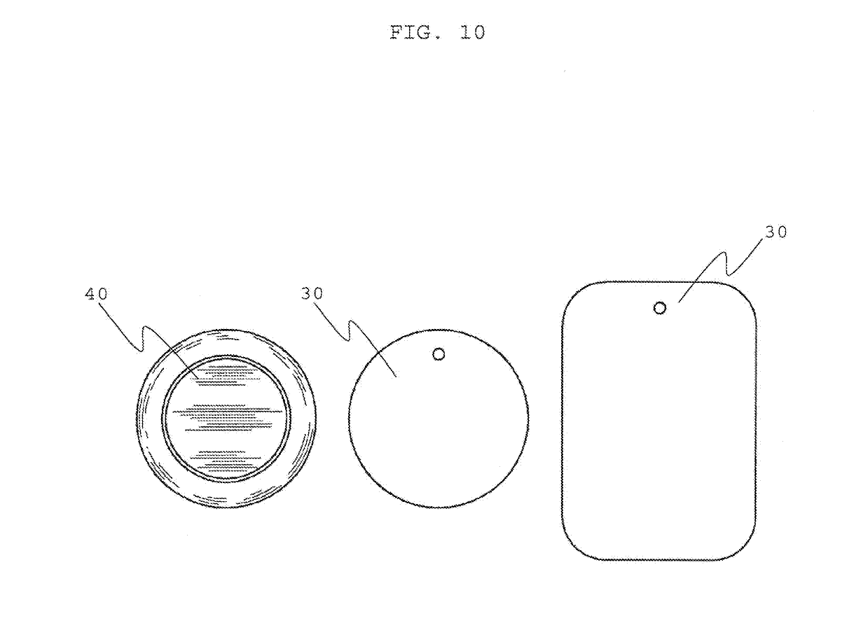

Preferably, the first member 30 is made of ferromagnetic material and the second member 50 is made of a magnet which produces magnetic flux. More specifically, the first member 30 may be made of steel, stainless steel, or iron. As in FIGS. 9 and 10, the first member 30 may be made of ferromagnetic metal plate.

The first member 30 is close enough to an outer surface 22 of the hard protective frame 20 and the magnet produces enough magnetic flux so that the support 40 attracts and retains the case 100 with the electronic device 300 installed therein in place.

Additionally, the support 40 and the case 100 create enough friction to prevent the case 100 from sliding on or slipping from the support 40 when the case 100 is magnetically retained by the support 40.

Alternatively, the second member 50 may be made of ferromagnetic material and the first member 30 may be made of a magnet which produces magnetic flux.

The body 42 of the support 40 may be geometrically a prism or cylinder. More preferably, the body 42 is substantially cylindrical as FIG. 6 or FIG. 7. Cylindrical shape is preferable in rotating the support 40 or case 100 with respect to each other. The plurality of legs 46 is attached about a center of the base 44 and preferably, there are four legs 46. Four legs 46 may form a square layout so that they can be easily inserted into an air vent of a vehicle.

As in FIGS. 9 and 10, the first member 30 may be a circular metal plate or a rectangular metal plate.

The soft protective cover 10 is made of soft material and the hard protective frame 20 is made of hard material. Preferably, the soft protective cover 10 is made of thermoplastic polyurethane and the hard protective frame 20 is made of polycarbonate.

As shown in FIG. 5, the soft protective cover 10 comprises a longitudinal recess 15 and the hard protective frame 20 comprises a longitudinal protrusion 25 such that the longitudinal recess 15 of the soft protective cover 10 receives the longitudinal protrusion 25 of the hard protective frame 20 therein for secure coupling between the soft protective cover 10 and the hard protective frame 20.

The soft protective cover 10 is sufficiently flexible to accept insertion of the electronic device 300 therein and sufficiently rigid to securely retain the inserted electronic device 300.

The magnetic mount 200 may further comprise a double-sided adhesive for attaching the first member 30 either to the soft protective cover 10 or to the hard protective frame 20. The double-sided adhesive may be a double-sided adhesive tape or sheet.

If the soft protective cover 10 has a recess (not shown) formed on the back panel 12 to receive the first member 30, the double-sided adhesive may be located in the recess to attach the first member 30 to the soft protective cover 10. The double-sided adhesive may be a double-sided adhesive tape or sheet.

If the hard protective frame 20 has a recess to receive the first member 30, the double-sided adhesive may be located in the recess to attach the first member 30 to the hard protective frame 20.

Alternatively, the magnetic mount 200 may further comprise two double-sided adhesives one of which is for attaching the first member 30 to the soft protective cover 10 and the other of which is for attaching the first member to the hard protective frame 20.

In case that the soft protective cover 10 has a first recess formed on the back panel 12 and the hard protective frame 20 has a second recess, and the first and second recesses form a housing to receive the first member 30 therein, two double-sided adhesives may be located in both of the recesses for attaching the first member 30 to the soft protective cover 10 and the hard protective frame 20.

The first member 30 may be attached either to the soft protective cover 10 or to the hard protective frame 20 by an adhesive such as glue, bond, paste, tape, double-sided adhesive, etc. The double-sided adhesive may be a double-sided adhesive tape or sheet.

In the alternative embodiment, a magnetic mount 200 for an electronic device 300 may comprise: a case 100 for receiving an electronic device therein; a first member 30 attached to a back of the case 100 by an adhesive; and a support 40 having a second member 50. The first and second members 30, 50 are magnetically attractable to each other for magnetically attracting and retaining the case 100 to the support 40. The adhesive may be glue, bond, paste, tape, double-sided adhesive, etc. The first member 30 may be a circular metal plate or a rectangular metal plate.

The first member 30 may be made of ferromagnetic material and the second member 50 may be made of a magnet which produces magnetic flux. More specifically, the first member 30 may be made of steel, stainless steel, or iron. Preferably, the first member 30 may be made of ferromagnetic metal plate.

Alternatively, the second member 50 may be made of ferromagnetic material and the first member 30 may be made of a magnet which produces magnetic flux.

Still in the alternative embodiment of the present invention, a magnetic mount 200 for an electronic device 300 comprises: a first member 30 to be attachable to a back of the electronic device 300 by an adhesive; and a support 40 having a second member 50. The first and second members 30, 50 are magnetically attractable to each other for magnetically attracting and retaining the case 100 to the support 40. In addition, one side of the adhesive is attached to the first member.

The first member 30 may be made of ferromagnetic material and the second member 50 may be made of a magnet which produces magnetic flux. The magnet produces enough magnetic flux so that the support 40 attracts and retains the electronic device 300. The support 40 and the first member 30 create enough friction to prevent the first member 30 from sliding on the support 40 when the electronic device 300 is magnetically retained by the support 40.

Another side of the adhesive may be covered with a release tape so that after removing the release tape, the another side of the adhesive can be attached to the back of the case.

The adhesive may be glue, bond, paste, tape, double-sided adhesive, or the like known in the art, but preferably, the adhesive is a double-sided adhesive. The double-sided adhesive may be a double-sided adhesive tape or sheet.

While the invention has been shown and described with reference to different embodiments thereof, it will be appreciated by those skilled in the art that variations in form, detail, compositions and operation may be made without departing from the spirit and scope of the invention as defined by the accompanying claims.

What is claimed is:

1. A magnetic mount (200) for an electronic device (300), comprising:
a case (100) which comprises
a soft protective cover (10) which comprises a back panel (12) to cover a back portion of the electronic device (300), and a side wall (14) extending from a top surface (11) of the back panel (12) along edges (13) of the back panel (12);
a hard protective frame (20) constructed to removably mount over the soft protective cover (10); and
a first member (30) placed between the soft protective cover (10) and the hard protective frame (20); and
a support (40) having a second member (50),
wherein the first and second members (30, 50) are magnetically attractable to each other for magnetically attracting and retaining the case (100) to the support (40).

2. The magnetic mount of claim 1, wherein the soft protective cover (10) has a recess (not shown) formed on the back panel (12) to receive the first member (30).

3. The magnetic mount of claim 1, wherein the hard protective frame (20) has a recess to receive the first member (30).

4. The magnetic mount of claim 1, wherein the soft protective cover (10) has a first recess formed on the back panel (12) and the hard protective frame (20) has a second recess, and wherein the first and second recesses form a housing to receive the first member (30) therein.

5. The magnetic mount of claim 1, wherein the first member (30) is made of ferromagnetic material and the second member (50) is made of a magnet which produces magnetic flux, and wherein the first member (30) is made of ferromagnetic metal plate.

6. The magnetic mount of claim 5, wherein the first member (30) is close enough to an outer surface (22) of the hard protective frame (20) and the magnet produces enough magnetic flux so that the support (40) attracts and retains the case (100) with the electronic device (300) installed therein.

7. The magnetic mount of claim 6, wherein the support (40) and the case (100) create enough friction to prevent the case (100) from sliding on the support (40) when the case (100) is magnetically retained by the support (40).

8. The magnetic mount of claim 1, wherein the support (40) comprises a body (42) and a plurality of legs (46), wherein the body (42) is substantially in a form of a geometric prism, or cylinder which has two bases (43, 44) facing each other wherein the legs (46) are attached to one of the two bases (43, 44), wherein the second member (50) is placed in the body (42),
wherein when the case (100) is magnetically retained by the support (40), the base (43) of the body (42) and an outer surface (22) of the hard protective frame (20) create enough friction to prevent the case (100) from sliding on the base (43).

9. The magnetic mount of claim 8, wherein the plurality of legs (46) is constructed to support the case (100) when the case (100) is magnetically retained by the support (40) so that the case (100) stands on a flat surface.

10. The magnetic mount of claim 8, wherein the plurality of legs (46) are constructed to be received and retained by an air vent of a vehicle which is comprised of parallel vanes.

11. The magnetic mount of claim 1, wherein the second member (50) is made of ferromagnetic material and the first member (30) is made of a magnet which produces magnetic flux.

12. The magnetic mount of claim 1, wherein the first member (30) is a circular metal plate or a rectangular metal plate.

13. The magnetic mount of claim 1, further comprising a double-sided adhesive for attaching the first member (30) either to the soft protective cover (10) or to the hard protective frame (20).

14. The magnetic mount of claim 1, further comprising two double-sided adhesives one of which is for attaching the first member (30) to the soft protective cover (10) and the other of which is for attaching the first member to the hard protective frame (20).

15. The magnetic mount of claim 1, wherein the first member (30) is attached either to the soft protective cover (10) or to the hard protective frame (20) by an adhesive.

16. A magnetic mount (200) for an electronic device (300), comprising:
a case (100) for receiving an electronic device therein;
a first member (30) attached to a back of the case (100) by an adhesive; and
a support (40) having a second member (50),
wherein the first and second members (30, 50) are magnetically attractable to each other for magnetically attracting and retaining the case (100) to the support (40), wherein the first member (30) is made of ferromagnetic material and the second member (50) is made of a magnet which produces magnetic flux,
wherein the first member (30) is made of ferromagnetic metal plate,
wherein the first member (30) is a circular metal plate or a rectangular metal plate.

17. The magnetic mount of claim 16, wherein the adhesive is a double-sided tape.

18. A magnetic mount (200) for an electronic device (300), comprising:
a first member (30) to be attachable to a back of the electronic device (300) by an adhesive; and
a support (40) having a second member (50),
wherein the first and second members (30, 50) are magnetically attractable to each other for magnetically attracting and retaining the case (100) to the support (40),
wherein one side of the adhesive is attached to the first member,
wherein the first member (30) is made of ferromagnetic material and the second member (50) is made of a magnet which produces magnetic flux,
wherein the magnet produces enough magnetic flux so that the support (40) attracts and retains the electronic device (300),
wherein the support (40) and the first member (30) create enough friction to prevent the first member (30) from sliding on the support (40) when the electronic device (300) is magnetically retained by the support (40).

19. The magnetic mount of claim 18, wherein another side of the adhesive is covered with a release tape so that after removing the release tape, the another side of the adhesive can be attached to the back of the case.

20. The magnetic mount of claim 19, wherein the adhesive is a double-sided tape.
